(19) United States
(12) Patent Application Publication
(10) Pub. No.: US 2026/0367163 A1
(43) Pub. Date: Nov. 19, 2026

(54) METHOD, APPARATUS, AND SYSTEM OF DETERMINING STATE OF CHARGE THRESHOLDS

(71) Applicant: HERE GLOBAL B.V., EINDHOVEN (NL)

(72) Inventors: ADVAIT MOHAN RAUT, MAHARASHTRA (IN); AMARNATH NAYAK, MUMBAI (IN); ALEX AVERBUCH, BUFFALO GROVE, IL (US)

(73) Assignee: HERE GLOBAL B.V., EINDHOVEN (NL)

(21) Appl. No.: 19/207,397

(22) Filed: May 14, 2025

(51) Int. Cl. G01R 31/387; B60L 58/13; G01C 21/34; G01R 31/392

(52) U.S. Cl. CPC G01R 31/387; B60L 58/13; G01C 21/3469; G01R 31/392; B60L 2260/52; B60L 2260/54

(57) ABSTRACT

An approach is provided for determining lower and upper SoC thresholds and providing a vehicle navigation function based on the thresholds. The approach involves receiving training data indicating features of vehicles and trips taken by the vehicles and training a machine learning model to generate a lower state of charge (SoC) threshold and an upper SoC threshold for a vehicle based on the training data. The approach further involves receiving input data associated with the vehicle, where the input data corresponds to the training data. The approach further involves causing the machine learning model to output the lower SoC threshold and the upper SoC threshold based on the input data, generating a vehicle navigation function based on the lower SoC threshold and the upper SoC threshold, and outputting the vehicle navigation function to the vehicle, a user equipment associated with a user of the vehicle, or a combination thereof.

### BACKGROUND

Electric vehicles (EVs) rely on rechargeable lithium-ion battery systems, which naturally degrade over time due to various factors such as charge/discharge cycles, charging rates, and state-of-charge (SOC) levels. In some cases, performance and longevity of such battery systems may further degrade based on how users operate the vehicle and manage charging sessions for the vehicles. For example, lithium-ion batteries experience increased stress when operated at very low SOC levels due to the potential for lithium plating and increased internal resistance. Further, the SOC level at which charging should cease is another critical factor in battery health. For example, fully charging a battery to 100% can accelerate degradation due to prolonged exposure to high voltage, leading to electrolyte breakdown and capacity loss. Thus, determining thresholds at which charging should commence and terminate is crucial for prolonging battery life.

While EV users may arbitrarily set such thresholds, the user-selected thresholds may not be optimal for improving the performance and longevity of the EV battery systems because the ideal thresholds at which EV charging should begin and terminate can vary based on various factors, such as environmental conditions, vehicle maneuvers, road attributes, etc. Since the user-selected thresholds typically remain static and do not account for such factors, battery management for such EV battery systems are typically suboptimal.

### SOME EXAMPLE EMBODIMENTS

Therefore, there is a need for an approach for determining lower and upper SoC thresholds based on features of EVs and various trip-related attributes and providing trip planning that incorporates EV charging sessions based on the thresholds.

According to one embodiment, an apparatus comprising at least one processor and at least one non-transitory memory including computer program code instructions is described. The computer program code instructions configured to, when executed, cause the apparatus to: receive training data indicating features of vehicles and trips taken by the vehicles; train a machine learning model to generate a lower SoC threshold and an upper SoC threshold for a vehicle based on the training data; receive input data associated with the vehicle, the input data corresponding to the training data; cause the machine learning model to output the lower SoC threshold and the upper SoC threshold based on the input data; generate a vehicle navigation function based on the lower SoC threshold and the upper SoC threshold; and output the vehicle navigation function to the vehicle, a user equipment associated with a user of the vehicle, or a combination thereof.

In certain apparatus embodiments, the lower SoC threshold and the upper SoC threshold define a recommended range for maintaining a SoC of the vehicle during a trip to be taken by the vehicle.

In certain apparatus embodiments, the features indicate charging sessions of the vehicles, and the attributes indicate, for each one of the one or more vehicle charging sessions: (i) a first SoC at which said one of the one or more vehicle charging sessions initiated; and (ii) a second SoC at which said one of the one or more vehicle sessions terminated.

In certain apparatus embodiments, the features indicate: (i) one or more types of charging provided by charging points to the vehicles during the charging sessions; (ii) a duration of each of the one or more vehicle charging sessions; or (iii) a combination thereof.

In certain apparatus embodiments, the features indicate, for each one of the vehicles: (i) a state of health (SoH) of a battery of said one of the vehicles; (ii) an energy ratio; or (iii) a combination thereof.

In certain apparatus embodiments, the features indicate attributes of the vehicles, and wherein the attributes indicate: (i) vehicle power supply information; (ii) vehicle specification; or (iii) a combination thereof.

In certain apparatus embodiments, the features indicate: (i) one or more road attributes of the trips; (ii) driving behaviors associated with the vehicles; (iii) one or more weather conditions associated with the trips; or (iv) a combination thereof.

In certain apparatus embodiments, the one or more road attributes indicate, for one or more road segments of the trips: (i) a road quality; (ii) a functional class; (iii) a speed limit; (iv) elevation information; (v) a coefficient of friction; (vi) an effective gradient; or (vii) a combination thereof.

In certain apparatus embodiments, to generate the vehicle navigation function, the computer program code instructions are configured to, when executed, cause the apparatus to: generate a trip for the vehicle that incorporates one or more charging sessions at one or more charging points during one or more periods of the trip such that a SoC of the vehicle is greater than the lower SoC threshold and lesser than the upper SoC threshold during the trip; and generate vehicle maneuver instructions for traversing the trip as the vehicle navigation function.

According to another embodiment, a non-transitory computer-readable storage medium having computer program code instructions stored therein is described. The computer program code instructions, when executed by at least one processor, cause the at least one processor to: receive training data indicating features of vehicles and trips taken by the vehicles; train a machine learning model to generate a lower SoC threshold and an upper SoC threshold for a vehicle based on the training data; receive input data associated with the vehicle, the input data corresponding to the training data; cause the machine learning model to output the lower SoC threshold and the upper SoC threshold based on the input data; generate a vehicle navigation function based on the lower SoC threshold and the upper SoC threshold; and output the vehicle navigation function to the vehicle, a user equipment associated with a user of the vehicle, or a combination thereof.

According to another embodiment, a method of determining upper and lower thresholds and providing a vehicle navigation function based on the thresholds is described. The method includes: receiving training data indicating features of vehicles and trips taken by the vehicles; training a machine learning model to generate a lower state of charge (SoC) threshold and an upper SoC threshold for a vehicle based on the training data; receiving input data associated with the vehicle, the input data corresponding to the training data; causing the machine learning model to output the lower SoC threshold and the upper SoC threshold based on the input data; generating a vehicle navigation function based on the lower SoC threshold and the upper SoC threshold; and outputting the vehicle navigation function to the vehicle, a user equipment associated with a user of the vehicle, or a combination thereof.

In addition, for various example embodiments described herein, the following is applicable: a computer program product may be provided. For example, a computer program product comprising instructions which, when the program is executed by a computer, cause the computer to perform any one or any combination of methods (or processes) disclosed.

In addition, for various example embodiments of the invention, the following is applicable: a method comprising facilitating a processing of and/or processing (1) data and/or (2) information and/or (3) at least one signal, the (1) data and/or (2) information and/or (3) at least one signal based, at least in part, on (or derived at least in part from) any one or any combination of methods (or processes) disclosed in this application as relevant to any embodiment of the invention.

For various example embodiments of the invention, the following is also applicable: a method comprising facilitating access to at least one interface configured to allow access to at least one service, the at least one service configured to perform any one or any combination of network or service provider methods (or processes) disclosed in this application.

For various example embodiments of the invention, the following is also applicable: a method comprising facilitating creating and/or facilitating modifying (1) at least one device user interface element and/or (2) at least one device user interface functionality, the (1) at least one device user interface element and/or (2) at least one device user interface functionality based, at least in part, on data and/or information resulting from one or any combination of methods or processes disclosed in this application as relevant to any embodiment of the invention, and/or at least one signal resulting from one or any combination of methods (or processes) disclosed in this application as relevant to any embodiment of the invention.

For various example embodiments of the invention, the following is also applicable: a method comprising creating and/or modifying (1) at least one device user interface element and/or (2) at least one device user interface functionality, the (1) at least one device user interface element and/or (2) at least one device user interface functionality based at least in part on data and/or information resulting from one or any combination of methods (or processes) disclosed in this application as relevant to any embodiment of the invention, and/or at least one signal resulting from one or any combination of methods (or processes) disclosed in this application as relevant to any embodiment of the invention.

In various example embodiments, the methods (or processes) can be accomplished on the service provider side or on the mobile device side or in any shared way between service provider and mobile device with actions being performed on both sides.

For various example embodiments, the following is applicable: An apparatus comprising means for performing a method of the claims.

Still other aspects, features, and advantages of the invention are readily apparent from the following detailed description, simply by illustrating a number of particular embodiments and implementations, including the best mode contemplated for carrying out the invention. The invention is also capable of other and different embodiments, and its several details can be modified in various obvious respects, all without departing from the spirit and scope of the invention. Accordingly, the drawings and description are to be regarded as illustrative in nature, and not as restrictive.

### BRIEF DESCRIPTION OF THE DRAWINGS

The embodiments of the invention are illustrated by way of example, and not by way of limitation, in the figures of the accompanying drawings:

FIG. 1 illustrates a diagram of a system capable of determining lower and upper SoC thresholds, according to an embodiment;

FIG. 2 illustrates a diagram of an example scenario of acquiring training data, according to an embodiment;

FIG. 3 illustrates a diagram of components of an assessment platform of FIG. 1, according to an embodiment;

FIG. 4 illustrates a diagram of an example scenario of strategically planning a charging session for an EV, according to an embodiment;

FIG. 5 illustrates a diagram of an example user interface displaying navigation-related information and a lower SoC threshold recommendation, according to an embodiment;

FIG. 6 illustrates a diagram of an example user interface displaying navigation-related information and an upper SoC threshold recommendation, according to an embodiment;

FIG. 7 illustrates a flowchart of a process for determining lower and upper SoC thresholds and generating a vehicle navigation function based on the thresholds, according to an embodiment;

FIG. 8 illustrates a diagram of a database of FIG. 1, according to an embodiment;

FIG. 9 illustrates a computer system upon which an embodiment of the invention may be implemented;

FIG. 10 illustrates a diagram of a chip set upon which an embodiment of the invention may be implemented; and

FIG. 11 illustrates a diagram of exemplary components of a mobile terminal capable of operating in the system of FIG. 1, according to one embodiment.

### DESCRIPTION OF SOME EMBODIMENTS

Examples of a method, apparatus, and computer program for determining lower and upper SoC thresholds is disclosed, according to various example embodiments. In the following description, for the purposes of explanation, numerous specific details are set forth in order to provide a thorough understanding of the embodiments of the invention. It is apparent, however, to one skilled in the art that the embodiments of the invention may be practiced without these specific details or with an equivalent arrangement. In other instances, well-known structures and devices are shown in block diagram form in order to avoid unnecessarily obscuring the embodiments of the invention.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. In addition, the embodiments described herein are provided by example, and as such, “one embodiment” can also be used synonymously as “one example embodiment.” Further, the terms “a” and “an” herein do not denote a limitation of quantity, but rather denote the presence of at least one of the referenced items. Moreover, various features are described which may be exhibited by some embodiments and not by others. Similarly, various requirements are described which may be requirements for some embodiments but not for other embodiments.

As discussed previously, an effective strategy for prolonging EV battery life is to manage thresholds for starting and terminating charging of an EV battery. Certain research and industry practices suggest that initiating charging at a lower SoC threshold, such as 20%, and stopping at an upper SoC threshold, such as 80%, can significantly reduce battery degradation and enhance long-term performance. Keeping the SoC within the upper and lower SoC thresholds ensures that the battery operates within a stable voltage range, preserving capacity. Furthermore, by maintaining the charge within the 20-80% range, the battery operates in a more thermally stable condition, reducing the likelihood of overheating. In addition to improving thermal management, such charging strategy also enhances regenerative braking efficiency. When an EV battery is at 100% charge, regenerative braking is often limited or disabled because there is no room to store additional energy. Stopping charging at 80% ensures that regenerative braking can function effectively, improving overall energy efficiency and reducing brake wear.

While setting the thresholds for starting and terminating EV charging to common values, such as 20% and 80%, may be practical for increasing the longevity of EV batteries, such practices may not be optimal for certain situations. For example, in cold weather conditions, raising the lower SoC threshold (e.g., from 20% to 30-40%) may help prevent battery performance issues in extreme cold, as low charge levels can reduce power output and efficiency. Specifically, at low SoC levels, an EV battery operates with lower voltage, and in cold conditions, internal resistance of the battery inevitably increases. Such combination can cause voltage sag, leading to reduced power output and potential system shutdowns. Thus, raising the lower SoC limit (e.g., from 20% to 30-40%) ensures the battery maintains a more stable voltage, reducing stress on the cells and preventing performance issues.

By way of another example, if an EV is regularly driven at high speeds or undergoes frequent rapid acceleration, slightly lowering the upper SoC threshold (e.g., from 80% to 70-75%) may enhance the longevity of the EV battery, as such practice can reduce battery stress during high power demand. Specifically, when an EV battery is at a high state of charge, the battery has higher internal resistance, which increases heat generation when delivering power. High-performance driving (e.g., rapid acceleration, high-speed driving) demands more energy, which can accelerate lithium-ion degradation when combined with high voltage levels. Additionally, heat is a major factor in battery degradation, and pushing an already high-charged battery to peak performance can cause greater thermal stress. Thus, keeping the upper SoC threshold slightly lower (e.g., 70-75%) can help reduce peak voltage stress and thermal load.

By way of another example, if an EV is expected to frequently travel on uneven terrains, such as hills and roadways on mountains, altering the lower and upper SoC thresholds (e.g., from 20% to 25-30% and from 80% to 70-75%) may benefit EV battery longevity. Specifically, driving uphill requires significantly more power from the battery, thus leading to faster discharge rates and higher heat generation. If the battery regularly depletes to 20% or lower on steep inclines, the battery may experience deep discharge stress, which can accelerate degradation. Raising the lower limit slightly (e.g., 25-30%) ensures that the battery maintains a healthier voltage range, thus reducing the risk of cell damage due to excessive depletion. Additionally, frequent uphill driving generates heat due to high power draw, and excessive battery heat is one of the primary causes of battery degradation. If an EV starts a hilly route with a high SoC (e.g., 80%), additional heat from regenerative braking on the descent can further stress the battery. Therefore, keeping the charge level slightly lower before starting the trip (e.g., starting the trip at the SoC of 75% instead of 80%) can help manage thermal buildup and reduce long-term degradation.

While EV users may recognize the benefits of altering the lower and upper SoC thresholds from common levels under certain situations, the process for determining the ideal lower and upper SoC thresholds becomes convoluted when multiple conditions that can adversely impact the longevity of an EV battery occur concurrently. Additionally, necessary information for determining the ideal lower and upper SoC thresholds may not be readily available due to lack of resources. Manually acquiring such information adds significant time overhead and effort, thus adding complexity to trip planning or demotivating users from incorporating ideal lower and upper SoC thresholds for a trip.

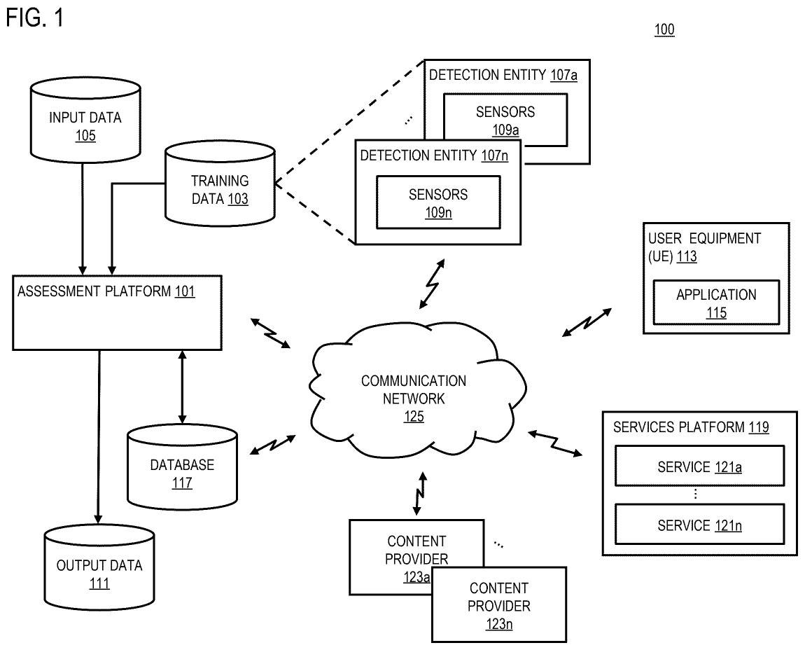

FIG. 1 illustrates a diagram of a system 100 capable of determining lower and upper SoC thresholds, according to an embodiment. Herein, a lower SoC threshold indicates a SoC threshold level for initiating EV charging, and an upper SoC threshold indicates a SoC threshold level for terminating EV charging. The system 100 includes an assessment platform 101 capable of determining the lower and upper SoC thresholds and using the thresholds to provide various applications, such as providing trip planning that incorporate charging sessions based on the thresholds and generating a vehicle navigation function based on the trip. The lower SoC threshold and the upper SoC threshold may define a recommended range for maintaining a SoC of an EV during a trip to be taken by the EV. In the illustrated embodiment, the assessment platform 101 recieves training data 103 and uses the training data 103 to train a machine learning model to generate lower and upper SoC thresholds for an EV of interest based on input data 105. The training data 103 may indicate features of vehicles, charging sessions for the vehicles, and trips taken by the vehicles. The EV of interest may indicate a target EV for generating the lower and upper SoC thresholds. In the illustrated embodiment, the training data 103 may be provided by detection entities 107a-107n (collectively referred as detection entities 107). In alternative embodiments, the training data 103 or one or more portions thereof may be provided by one or more other sources within or outside the system 100, such as a database, a server, etc.

Once the machine learning model is sufficiently trained, input data 105 may be provided to the machine learning model. The input data 105 may include features corresponding to the training data 103. For example, input data 105 may indicate one or more features of an EV of interest and one or more features of a trip to be taken by the EV of interest, such as environmental conditions and road attributes of the trip. The machine learning model uses the input data 105 to generate lower and upper SoC thresholds that are ideal for maintaining a SoC of the EV of interest during the trip. In the illustrated embodiment, the assessment platform 101 uses the lower and upper SoC thresholds to generate output data 111. In one embodiment, the output data 111 includes a vehicle navigation function for the EV of interest. For example, the assessment platform 101 may provide the vehicle navigation function by providing a trip that incorporates one or more charging sessions to ensure that the SoC of the vehicle of interest satisfies the lower SoC threshold and the upper SoC threshold during the trip (i.e., the SoC of the vehicle of interest is greater than the lower SoC threshold during the trip and lesser than the upper SoC threshold during the trip). By way of another example, the assessment platform 101 may generate vehicle maneuver instructions for the trip as a part of the vehicle navigation function. The vehicle maneuver instructions may be provided on a user interface, such as user equipment (UE) 113, for assisting a driver of the vehicle of interest or provided to a control system of the vehicle of interest to cause the vehicle of interest to autonomously traverse one or more road segments of the trip.

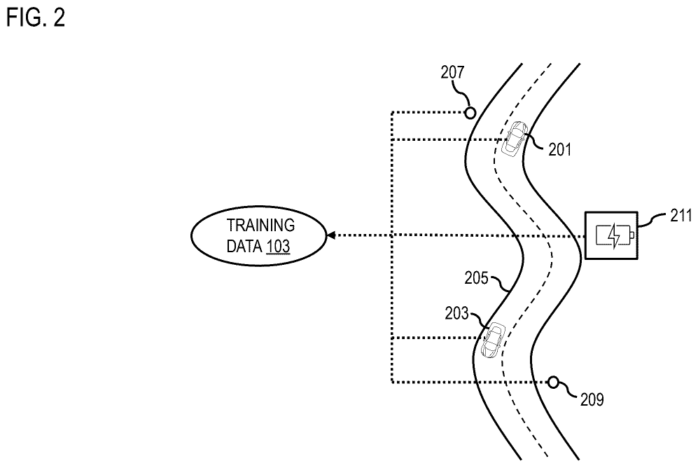

FIG. 2 illustrates a diagram of an example scenario 200 of acquiring the training data 103, according to an embodiment. In the illustrated embodiment, the scenario 200 indicates first and second EVs 201 and 203 on a roadway 205, first and second roadside sensors 207 and 209 positioned along the roadway 205, and an EV charging station 211 positioned along the roadway 205. In one embodiment, the first and second EVs 201 and 203, the first and second roadside sensors 207 and 209, the EV charging station 211 may be the detection entities 107 of FIG. 1. In the illustrated embodiment, each of the first and second EVs 201 and 203 is traversing a route involving the roadway 205 as a trip. In such embodiment, the trip includes a charging session at the EV charging station 211. In the illustrated embodiment, the training data 103 may be defined by data acquired by the first and second EVs 201 and 203, the first and second roadside sensors 207 and 209, and the EV charging station 211. In alternative embodiments, the training data 103 may be further defined by data provided by one or more databases (e.g., database 117), one or more other sources outside of the system 100 of FIG. 1 or outside the scenario 200 of FIG. 2, or a combination thereof.

In one embodiment, the training data 103 may indicate features of the first and second EVs 201 and 203, such as vehicle power supply information, vehicle specifications, or a combination thereof. In such embodiment, the vehicle power supply information may indicate: (i) battery size; (ii) battery weight; (iii) battery capacity; (iv) battery type (e.g., lithium-ion, zinc-ion, sodium-ion, etc.); (v) battery generation (e.g., 1^{st}, 2^{nd}, 3^{rd}, or 4^{th} battery generation); (vi) battery charging/discharging power at various SoC levels; (vii) a SoC of the EV battery; (viii) a state of health of the EV battery; (ix) an energy ratio; or (x) a combination thereof.

The vehicle specifications may indicate: (i) engine type; (ii) engine displacement; (iii) horsepower; (iv) torque; (v) top speed; (vi) transmission type; (v) drivetrain; (vi) vehicle dimensions; (vii) wheelbase; (viii) ground clearance; (ix) curb weight; (x) gross vehicle weight rating; (xi) front & rear suspension type; (xii) brake type; (xiii) anti-lock braking system (ABS); (xiv) wheel size; (xv) tire size, type and dimensions; (xvi) Advanced Driver Assistance Systems (ADAS) capabilities; (xvii) drive modes; or (xviii) a combination thereof.

As discussed above, the training data 103 may indicate a SoH of an EV battery, an energy ratio, or a combination thereof for each trip taken by an EV. In one embodiment, the SoH and the energy ratio indicate the effectiveness of maintaining a SoC level within a range between a lower SoC level and an upper SoC level for improving the longevity of an EV battery. In one embodiment, the energy ratio is a value ranging from 0 to 1, where the value indicates a condition of an EV battery. The value of 1 indicates that a battery is not impacted by any degradation, and the value of 0 indicates that the battery is completely degraded. Equation 1, as presented below, defines the energy ratio:

$$E R = \frac{{E}_{out 1}}{{E}_{out 2}} \qquad ( Equation 1 )$$

In Equation 1, ER is the energy ratio, Eₒᵤₜ₁ is a mean of an amount of energy given out by the battery in a “k” number of the latest discharge cycles, Eₒᵤₜ₂ is a mean of an amount of energy given out by the battery in the “k” number of the earliest discharge cycles.

In one embodiment, the training data 103 may indicate driving behaviors of the first and second EVs 201 and 203. In such embodiment, components of the first and second EVs 201 and 203, UE associated with the first and second EVs 201 and 203, or a combination thereof may collect information pertaining to the driving behaviors. For example, driver behavior data is gathered using, for example: (i) GPS tracking; (ii) on-board diagnostics (OBD-II) devices; (iii) telematics systems (iv) dashcams and/or in-vehicle cameras; (v) mobile applications and/or smartphone sensors; (vi) vehicle embedded systems; (vii) other in-vehicle sensors; or (viii) a combination thereof. Once collected, the data is structured into categorical data such as: (i) trip data indicating distance traveled, time of day, duration, and route; (ii) speed and acceleration data indicating average speed, rapid acceleration events, harsh braking, and cornering behavior; (iii) energy consumption data; (iv) distraction data indicating phone usage while driving and drowsiness detection; (v) event-based trigger data indicating collisions, sudden stops, and aggressive driving incidents; (vi) driver data indicating age and gender; or (vii) a combination thereof.

In one embodiment, the training data 103 may indicate, for each of the first and second EVs 201 and 203, one or more road attributes associated with the trip of each one of the first and second EVs 201 and 203 and one or more attribute associated with the environment of the trip. For example, the one or more road attributes indicate: (i) road quality; (ii) functional class (e.g., arterials, collectors, local roads, etc.); (iii) speed limit; (iv) elevation information; (v) average coefficient of friction; (vi) effective gradient; (vii) bumpiness factor; (viii) road width; (ix) lane count; (x) lane width; (xi) horizontal curvature; (xii) drainage system indicating presence of gutters, culverts, or ditches; (xiii) safety features indicating signage, road markings, guardrails, barriers, lighting, etc.; or (xiv) a combination thereof.

The road quality may indicate: (i) surface condition indicating pavement type, cracks and potholes, smoothness and roughness; (ii) structural integrity such as rutting and deformation, edge breaks and erosion, and load capacity; (iii) pavement age; or (iv) a combination thereof.

The elevation information may indicate: (i) a total elevation gain indicating the total amount of elevation gained over a road segment by summing all uphill sections in the road segment; (ii) a total elevation loss indicating the total amount of elevation lost over the road segment by summing all downhill sections in the road segment; (iii) a net elevation change indicating a difference between a starting and an ending elevations; (iv) a grade (or slope) expressed as a percentage; (v) a maximum/minimum elevation indicating the highest and lowest points along a road segment; (vi) an elevation profile indicating a graphical representation of elevation along the road segment; or (vii) a combination thereof.

The effective gradient indicates the actual or perceived difficulty of a road's incline, taking into account more than just the geometric slope of the road. For example, the effective gradient considers one or more factors such as rolling resistance, wind resistance, curvature and banking of the road, road surface conditions, or a combination thereof. An example Equation 2, as presented below, demonstrates an effective gradient that considers rolling resistance and aerodynamic resistance:

$${G}_{eff} = G + \frac{R}{cos ( θ )} + \frac{{F}_{w i n d}}{m g} \qquad ( Equation 2 )$$

In Equation 2, G_{eff} is the effective gradient, G is the geometric gradient (i.e., road slope), which is typically defined as tan (θ)×100, where θ is the incline angle, R is the rolling resistance coefficient, which depends on the road surface and tire type, cos (θ) accounts for the effect of incline on rolling resistance, F_{wind} is the wind resistance force, m is the mass of the vehicle, and g is the gravitational acceleration.

The bumpiness factor can be analyzed by using an elevation profile of a trip, where elevation is recorded as a function of distance traveled. The distance can be represented in absolute terms (such as miles or kilometers from the starting point) or parametrically (where the starting point is assigned a value of 0 and the destination a value of 1). Additionally, Fourier analysis can be applied to the elevation function to generate the bumpiness factor. Specifically, the bumpiness factor can be derived by: (i) applying high-frequency filters to the elevation function to isolate rapid elevation changes (e.g., distance of meters or fractions of a meter); (ii) computing the total absolute value of elevation changes in the filtered function; and (iii) normalizing the total elevation change by dividing the total elevation change by the total trip length. The normalized value serves as a quantitative measure of a road's bumpiness.

In one embodiment, the one or more attribute associated with the environment of the trip may indicate: (i) a weather condition of the trip; (ii) one or more points-of-interest connected to a road segment; (iii) local land use data indicating urban, suburban, or rural environment impacting road design and usage; or (iv) a combination thereof.

In one embodiment, the training data 103 may indicate attributes regarding any charging sessions of each one of the first and second EVs 201 and 203. For example, the attributes regarding a charging session for each of the of the first and second EVs 201 and 203 may indicate: (i) a first SoC level at which the charging session initiated; (ii) a second SoC level at which the charging session terminated; (iii) a charging duration of the charging session; (iv) a type of charging provided during the charging session; (v) a number of charge cycles; (vi) a number of discharge cycles; (vii) battery charge or discharge rate; or (v) a combination thereof. A charge cycle indicates one complete charge and discharge of a battery. A discharge cycle refers to one complete use of an amount of energy equal to 100% of a battery's capacity, regardless of whether the usage happens in one go or across multiple smaller discharges. In the illustrated embodiment, the attribute regarding the charging session for each one of the first and second EVs 201 and 203 may be provided by the charging station 211, the corresponding one of the first and second EVs 201 and 203, or a combination thereof.

In one embodiment, the training data 103 may indicate, for each of the first and second EVs 201 and 203, trip-related attributes, such as: (i) a total length of one or more routes defining a trip; (ii) a total amount of EV battery energy spent for the trip; (iii) a total amount of EV battery energy spent on each discharge cycle; (iv) vehicle speed and acceleration levels; (v) vehicle or battery temperature levels; (vi) regenerative braking contribution indicating an amount of energy recovered through regenerative braking; (vii) the lowest SoC level of the battery during the trip; (viii) the highest SoC level of the battery during the trip; or (ix) a combination thereof. In the illustrated embodiment, the trip-related attributes may be provided by the first and second EVs 201 and 203.

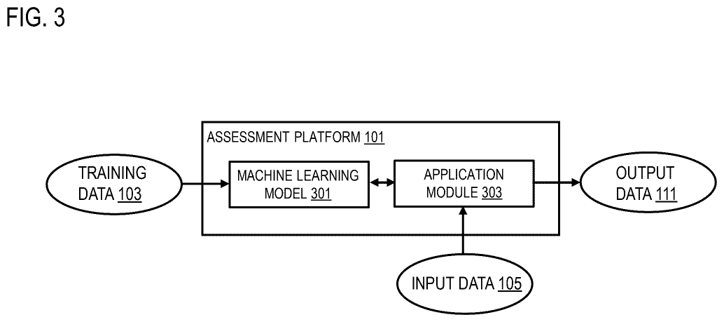

FIG. 3 illustrates a diagram of components of the assessment platform 101, according to an embodiment. In the illustrated embodiment, the assessment platform 101 includes a machine learning model 301 and an application module 303. In the illustrated embodiment, the assessment platform 101 receives the training data 103 and trains the machine learning model 301 based on the training data 103. In one embodiment, prior to training, the training data 103 may be structured into a dataset including input-output pairs, where the output includes features such as the lowest SoC level of an EV battery during a trip and the highest SoC level of the EV battery during the trip, and the input includes features such as vehicle power supply information, vehicle specification, driving behavior, road attributes, environmental attributes, attributes regarding EV charging sessions, trip-related attributes, etc.

During training, the machine learning model 301 learns the relationship between the input features of the dataset and the optimal SoC thresholds by minimizing the error between predicted and actual values. In one embodiment, a regression algorithm, such as a neural network or gradient-boosted decision trees, may be employed to approximate such mapping. In one embodiment, loss function, such as mean squared error (MSE), quantifies the difference between predicted thresholds and the true values, guiding the optimization process. Through multiple iterations of forward and backward propagation, the machine learning model 301 adjusts internal parameters using gradient descent or a similar optimization technique to reduce the prediction error. In one embodiment, during training, the machine learning model 301 may be provided with labeled examples where the target outputs (i.e., the lower and upper SoC thresholds) have historically led to the best battery longevity, as determined by metrics like a SoH of an EV battery or an energy ratio. The machine learning model 301 learns to map input features (e.g., the input data 105) to lower and upper SoC thresholds that minimize degradation rather than just being statistically probable. To ensure that the machine learning model 301 prioritizes longevity, labels in the dataset reflect the thresholds that resulted in the slowest capacity degradation.

Once the machine learning model 301 is trained, the trained machine learning model 301 enters an inference phase and may receive real-time or new input data, such as the input data 105. In one embodiment, the input data 105 may be provided from the EV of interest, UE associated with the EV of interest (e.g., UE 117), database 117, one or more services 121a-121n (collectively referred as services 121), one or more content providers 123a-123n (collectively referred as content providers 123), or a combination thereof. In one embodiment, the input data 105 may be provided as a request for the lower and upper SoC thresholds for the EV of interest, a request for a navigation function for the EV of interest based on the lower and upper SoC thresholds, or a combination thereof. In one embodiment, the input data 105 may include one or more features corresponding to the training data 103. For example, the input data 105 may include features of the EV of interest and a trip to be taken by the EV of interest. Such features include: (i) vehicle power supply information; (ii) vehicle specification; (iii) a driving behavior of a user of the vehicle of interest; (iv) one or more road attributes associated with the trip; (iv) one or more attributes associated with the environment of the trip; (v) attributes regarding any charging sessions of the EV of interest; (vi) trip-related attributes associated with the trip (e.g., a starting location of the trip, a destination location of the trip, a distance from the starting location to the destination location, etc.); (vii) a SoH of the battery of the EV of interest; (viii) an energy ratio of the EV of interest; or (ix) a combination thereof.

During the inference phase, the trained machine learning model 301 may process the input data 105 by passing the data through the trained regression function, which calculates the most probable lower and upper SoC thresholds based on learned patterns. In one embodiment, the trained machine learning model 301 may predict the optimal lower and upper SoC thresholds for improving battery longevity based on the training applied via the training data 103. For example, when given the input data 105, the trained machine learning model 301 may evaluate conditions as indicated by the input data 105 and outputs the lower and upper SoC thresholds that have historically led to minimal degradation in similar situations. As such, the trained machine learning model 301 may function as an EV battery longevity optimizer by leveraging historical patterns of degradation to recommend lower and upper SoC thresholds that lead to the least stress on the EV battery over extended use.

In one embodiment, prior to training the machine learning model 301, the assessment platform 101 may select a subset of the training data 103, where the subset indicates events in which maintaining certain lower and upper SoC levels in EV batteries during trips resulted in optimal battery longevity (e.g., 1-2% battery capacity loss per year). In such embodiment, the subset may be identified by measuring a change in a SoH of an EV battery over time or a change in energy ratio over time. Once the subset is identified, the subset is used to train the machine learning model 301, thereby enabling the machine learning model 301 to predict the optimal lower and upper SoC thresholds for improving battery longevity during the inference phase.

In one embodiment, in addition to training the machine learning model 301 to generate lower and upper SoC thresholds for an EV, the assessment platform 101 may further train the machine learning model 301 to predict a total amount of EV battery energy required for a trip based on the training data 103. In such embodiment, the training data 103 may be structured into a dataset including input-output pairs, where the output includes a feature such as a total amount of EV battery energy spent on a trip taken by an EV, and the input includes features such as vehicle power supply information, vehicle specification, driving behavior, road attributes, environmental attributes, attributes regarding EV charging sessions, trip-related attributes, etc. The machine learning model 301 learns the relationship between the input features of the dataset and the output feature by minimizing the error between predicted and actual values. In one embodiment, a regression algorithm, such as a neural network or gradient-boosted decision trees, may be employed to approximate such mapping. Once the machine learning model 301 is trained, the trained machine learning model 301 may receive real-time or new input data, such as the input data 105, which include features of the EV of interest and a trip to be taken by the EV of interest. Then, the trained machine learning model 301 predicts the most probable amount of energy required for the trip based on learned patterns.

In one embodiment, the machine learning model 301 may be sequentially trained. In such embodiment, a dataset pertaining to a single trip taken by an EV is added to the training data 103. The dataset includes input-output pairs, where the output may include features such as the lowest SoC level of a battery of the EV during the trip and the highest SoC level of the EV battery during the trip, and the input may include features such as vehicle power supply information of the EV, vehicle specification of the EV, driving behavior of a driver of the EV during the trip, road attributes of the trip, environmental attributes of trip, attributes regarding EV charging sessions during the trip, other attributes related to the trip, etc. Multiple datasets can be added to the training dataset, and for each instance in which a dataset pertaining to a single trip taken by an EV is added to the training data, the machine learning model 301 is trained based on the training data 103 that includes said dataset. As such, the machine learning model 301 is trained iteratively, where data is processed in a sequence rather than all at once, thereby reducing computation load on the hardware that incorporates the machine learning model 301 and enabling the machine learning model 301 to adapt to new data dynamically.

In one embodiment, the trained the machine learning model 301 may be continuously improved by applying a feedback learning mechanism that compares the output of the machine learning model 301 to ground truth data and refining predictions output by the machine learning model 301 based on the comparison. For example, the output may be lower and upper thresholds for a trip and a predicted total amount of EV battery energy required for the trip, and the ground truth data may be SoH of the battery before and after the trip, the energy ratio before and after the trip, and the actual EV battery energy used during the trip. Based on the comparison between the output of the machine learning model 301 and the ground truth data, the trained machine learning model 301 may be further refined to improve predictions to be output by the model 301.

In the illustrated embodiment, the assessment platform 101 further includes the application module 303 that is configured to use the output of the machine learning mode 103 to generate the output data 111. In one embodiment, the output data 111 includes the lower and upper SoC thresholds for the EV of interest. In one embodiment, the output data 111 includes a vehicle navigation function for the EV of interest. For example, the vehicle navigation function involves using the lower and upper SoC thresholds generated by the machine learning model 103 to incorporate one or more charging sessions into the trip to ensure that the SoC of the EV of interest is greater than the lower SoC threshold during the trip and lesser than the upper SoC threshold during the trip.

In one embodiment, the one or more charging sessions is strategically planned for the trip to enable the EV of interest to travel at a maximum distance during the trip without compromising the lower SoC threshold and upper SoC threshold. In such embodiment, the application module 303 performs an iterative process. Specifically, the application module 303 receives the input data 105 including a starting location and a destination location for the EV of interest and uses the input data 105 to identify a first route from the starting location to the destination location. The application module 303 acquires information pertaining to the first route and supplements the input data 105 with the information. Then, the machine learning model 301 receives the input data 105 from the application module 303 and generates lower and upper SoC thresholds for the first route and an amount of energy required to traverse the first route. The application module 303 determines a difference between the current SoC level of the EV of interest to the lower SoC threshold, and the difference is compared against the amount of energy required to traverse the first route. If the difference is greater than the amount of energy, the application module 303 provides the first route and the lower and upper thresholds generated based on the first route as the output data 111.

Conversely, if the difference is equal to or less than the amount of energy required to traverse the first route, the application module 303 identifies one or more charging points within a proximity of the first route (e.g., 5 miles) and identifies a second route for each charging point of the one or more charging points, where the second route starts from the starting location and ends at said charging point. The application module 303 further obtains information pertaining to each second route and supplements the input data 105 with the information. Then, based on the input data 105, the machine learning model 301 generates lower and upper SoC thresholds for traversing each second route and an amount of energy required to traverse each second route. The application module 303 calculates a difference between the current SoC level of the EV of interest and the lower SoC threshold generated for each second route and compares the difference to the amount of energy required to traverse each second route.

Based on the comparison, the application module 303 selects a second route among the one or more second routes generated for the one or more charging points, such that: (i) the amount of energy required for traversing the selected second route is less than the difference between the current SoC level of the EV of interest and the lower SoC threshold generated for the selected second route; and (ii) the total length of the selected second route is the greatest among the one or more second routes. Then, the selected second route and the lower and upper threshold for traversing the selected second route are provided as a part of the output data 111.

The application module 303 updates: (i) the starting location as the location of the charging point at the end of the selected second route; and (ii) the current SoC level of the EV of interest as an upper SoC threshold for a subsequent route that starts from the updated starting location and ends at the destination location or another charging point that is closer to the destination location than the updated starting location, where the upper SoC threshold is generated by the machine learning model 301 based on information pertaining to the subsequent route. The application module 303 repeats the iterative process based on the updated data until the entire trip for the EV of interest is established.

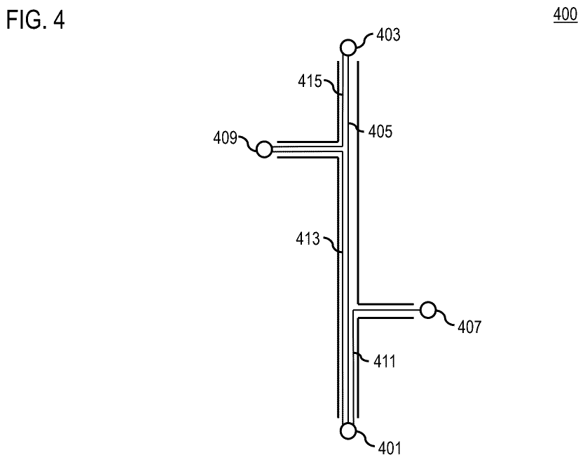

For example, FIG. 4 illustrates an example scenario 400 of strategically planning a charging session for an EV. In the illustrated example, the EV is located at a first location 401 and is planning to travel to a destination location 403. The assessment platform 101: (i) receives the input data 105 including information indicating the first location 401 and the destination location 403; (ii) determines a first route 405 based on the input data 105; (iii) generates lower and upper SoC thresholds for the first route 405 and an amount of energy required to traverse the first route 405; (iv) determines a difference between the current SoC level of the EV and the lower SoC threshold; and (v) compares the difference against the amount of energy required to traverse the first route 405.

In the scenario 400, the assessment platform 101 determines that the difference is less than the amount of energy required to traverse the first route 405, thus indicating that the EV will be unable to traverse the first route 405 without compromising the lower SoC threshold. As such, the assessment platform 101 identifies: (i) first and second charging points 407 and 409 that are within a proximity of the first route 405; (ii) a second route 411 starting from the starting location 401 and ending at the location of the first charging point 407; and (iii) a third route 413 starting from the starting location 401 and ending at the location of the second charging point 409. The assessment platform 101 further: (i) obtains information pertaining to the second route 411 and the third route 413; (ii) uses the information to generate lower and upper SoC thresholds for traversing each of the second route 411 and the third route 413 and an amount of energy required to traverse each of the second route 411 and the third route 413; (iii) calculates a difference between the current SoC level of the EV and the lower SoC threshold generated for each of the second route 411 and the third route 413; and (iv) compares the difference to the amount of energy required to traverse each of the second route 411 and the third route 413.

Based on the comparison, the assessment platform 101 selects the third route 413 because: (i) the amount of energy required for traversing the third route 413 is less than the difference between the current SoC level of the EV and the lower SoC threshold generated for the third route 413; and (ii) the total length of the third route 413 is greater than the total length of the second route 411. As such, the third route 413 and the lower and upper thresholds for traversing the third route 413 are provided as a part of the output data 111.

Additionally, the assessment platform 101 determines a fourth route 415 starting from the location of the second charging point 409 and ending at the destination location 403 based on the input data 105 and generates lower and upper SoC thresholds for the fourth route 415 and an amount of energy required to traverse the fourth route 415. It is assumed that that the EV will be charged to the upper SoC threshold for the fourth route 415 when the EV is at the second charging 409. As such, the assessment platform 101 determines a difference between the upper SoC threshold for the fourth route 415 and the lower SoC threshold for the fourth route 415 and compares the difference against the amount of energy required to traverse the fourth route 415.

Based on the comparison, the assessment platform 101 determines that the difference is greater than the amount of energy required to traverse the fourth route 415. As such, the fourth route 415 and the lower and upper threshold for traversing the fourth route 415 are provided as a part of the output data 111.

Returning to FIG. 3, the application module 303 may generate vehicle maneuver instructions for traversing the trip as the vehicle navigation function. For example, the vehicle maneuver instructions may include a step-by-step instruction for maneuvering a vehicle during the trip based on map data and real-time data pertaining to the current environment of the vehicle. In one embodiment, the vehicle navigation function may be provided on a user interface, such as a user interface of an infotainment system of a vehicle, user equipment, such as the UE 113, or a combination thereof. In such embodiment, the vehicle navigation function may be presentations of various information such as: (i) a route to a destination; (ii) graphical representations of a real-time perspective view of a region including a vehicle that is utilizing the vehicle navigation function; (iii) a heading and position of the vehicle; (iv) objects within the region (e.g., roads, road objects, buildings, points-of-interest, other vehicles, etc.); (v) a maneuver instruction for a current road portion on which the vehicle is currently traversing; (vi) one or more subsequent maneuver instructions for one or more subsequent road portions of the route; (vii) a lower SoC threshold for the route; (viii) an upper SoC threshold for an upcoming charging session; (ix) estimated time of arrival (ETA); (x) a speed limit for the road portion; (xi) an amount of distance of travel for the road portion; (xii) a current SoC of the vehicle; (xiii) names of the road portion and one or more subsequent road portions of the route; (xiv) an amount of energy required to traverse from the current location of the vehicle to the destination; (xv) other relevant information pertaining to navigation of the route; or (xvi) a combination thereof. In one embodiment, the vehicle navigation function may be autonomous vehicle maneuver instructions/control commands, and the application module 303 may output the vehicle navigation function to vehicles with autonomous driving capabilities, thereby enabling such vehicles to autonomously traverse trips thereof.

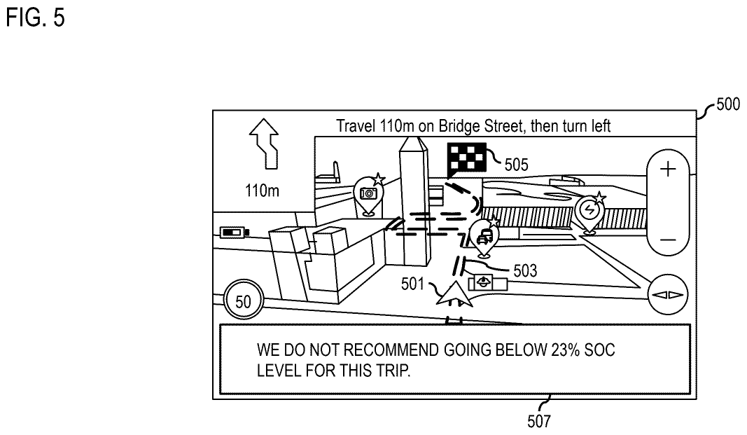

FIG. 5 illustrates a diagram of an example user interface 500 displaying navigation-related information and a lower SoC threshold recommendation, according to an embodiment. In the illustrated embodiment, the example user interface 500 may be a part of an in-vehicle navigation system of an EV. In one embodiment, the vehicle navigation function generated by the application module 303 may cause the in-vehicle navigation system to generate the navigation-related information on the user interface 500. In the illustrated embodiment, the example user interface 500 includes the navigation related information, such as graphical representations of a real-time perspective view of a region including an avatar 501 indicating a current position and heading of the EV. The graphical representations further include a route 503 to a destination 505 and a message 507 including a lower SoC threshold recommendation generated for the route 503, which states “WE DO NOT RECOMMEND GOING BELOW 23% SOC LEVEL FOR THIS TRIP.”

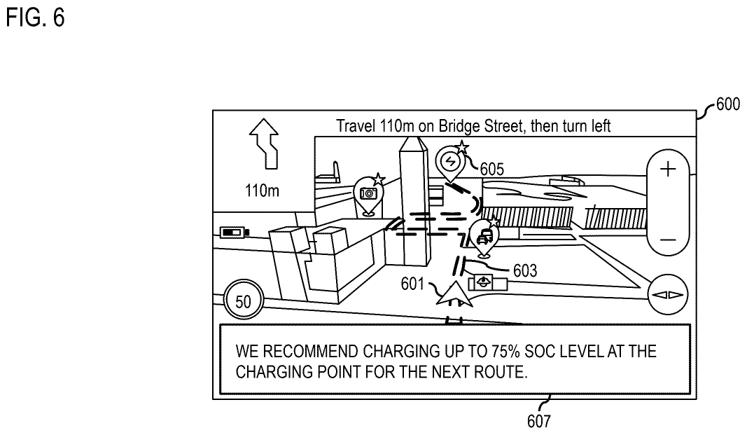

FIG. 6 illustrates a diagram of an example user interface 600 displaying navigation-related information and an upper SoC threshold recommendation, according to an embodiment. In the illustrated embodiment, the example user interface 600 may be a part of an in-vehicle navigation system of an EV. In one embodiment, the vehicle navigation function generated by the application module 303 may cause the in-vehicle navigation system to generate the navigation-related information on the user interface 600. In the illustrated embodiment, the example user interface 600 includes the navigation related information, such as graphical representations of a real-time perspective view of a region including an avatar 601 indicating a current position and heading of the EV and a route 603 to a charging point 605. It is assumed that the route 603 is a part of a plurality of routes generated for the EV as a trip. As such, the graphical representations further include a message 607 indicating an upper SoC threshold recommendation generated for the subsequent route of the trip, which states “WE RECOMMEND CHARGING UP TO 75% SOC LEVEL AT THE CHARGING POINT FOR THE NEXT ROUTE.”

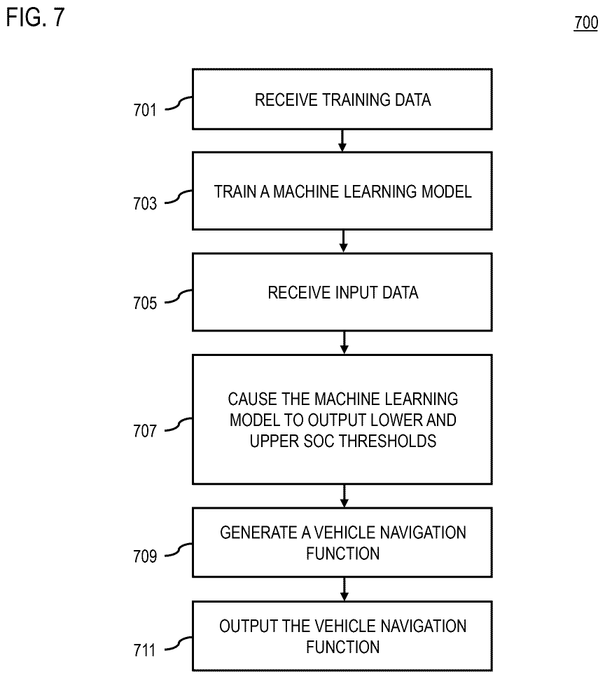

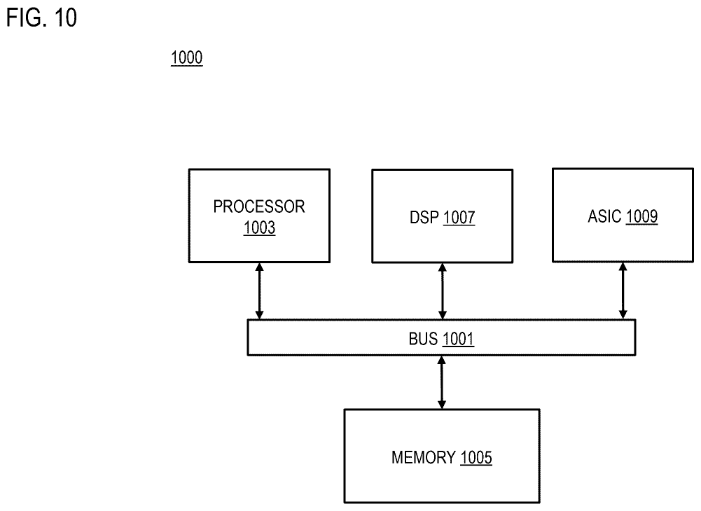

FIG. 7 is flowchart of a process for determining lower and upper SoC thresholds and generating a vehicle navigation function based on the thresholds, according to an embodiment. In various embodiments, the assessment platform 101 may perform one or more portions of the process 700 and may be implemented in, for instance, a chip set including a processor and a memory as shown in FIG. 10. As such, the assessment platform 101 can provide means for accomplishing various parts of the process 700, as well as means for accomplishing embodiments of other processes described herein in conjunction with other components of the system 100. Although the process 700 is illustrated and described as a sequence of steps, it is contemplated that various embodiments of the process 700 may be performed in any order or combination and need not include all of the illustrated steps. Herein, the process 700 will be described in conjunction with FIG. 1.

In step 701, the assessment platform 101 receives training data (such as the training data 103) indicating features of EVs and trips taken by the EVs. For example, such features may indicate vehicle power supply information of the EVs, vehicle specifications of the EVs, driving behaviors associated with the EVs, one or more road attributes associated with the trips, one or more attribute associated with the environment of the trips, attributes regarding charging sessions of the EVs, trip-related attributes associated with the EVs, or a combination thereof. In one embodiment, the training data may be structured into a dataset including input-output pairs, where the output includes features such as the lowest SoC level of an EV battery during a trip and the highest SoC level of the EV battery during the trip, and the input includes features such as vehicle power supply information, vehicle specification, driving behavior, road attributes, environmental attributes, attributes regarding EV charging sessions, trip-related attributes, etc. In one embodiment, the assessment platform 101 may receive the training data from one or more detection entities 107, the database 117, the services platform 119, the content providers 123, or a combination thereof.

In step 703, the assessment platform 101 trains a machine learning model to generate the lower SoC threshold and an upper SoC threshold for an EV of interest based on the training data. During training, the machine learning model learns the relationship between the input features of the dataset and the optimal SoC thresholds by minimizing the error between predicted and actual values. In one embodiment, a regression algorithm, such as a neural network or gradient-boosted decision trees, may be employed to approximate such mapping.

In step 705, the assessment platform 101 receives input data (such as the input data 105) associated with the EV of interest. In one embodiment, the input data corresponds to the training data. For example, the input data may include features of the EV of interest and a trip to be taken by the EV of interest. Such features include: (i) vehicle power supply information; (ii) vehicle specification; (iii) a driving behavior of a user of the vehicle of interest; (iv) one or more road attributes associated with the trip; (iv) one or more attributes associated with the environment of the trip; (v) attributes regarding any charging sessions of the EV of interest; (vi) trip-related attributes associated with the trip (e.g., a starting location of the trip, a destination location of the trip, a distance from the starting location to the destination location, etc.); (vii) a SoH of the battery of the EV of interest; (viii) an energy ratio of the EV of interest; or (ix) a combination thereof. In one embodiment, the input data 105 may be provided from the EV of interest, UE associated with the EV of interest (e.g., UE 117), the database 117, one or more of the services 121, one or more of the content providers 123, or a combination thereof.

In step 707, the assessment platform 101 causes the machine learning model to output the lower and upper SoC thresholds based on the input data. For example, the machine learning model may process the input data by passing the data through the trained regression function, which calculates the most probable lower and upper SoC thresholds based on learned patterns. In one embodiment, the machine learning model may predict the optimal lower and upper SoC thresholds for improving battery longevity based on the training applied via the training data. For example, when given the input data, the machine learning model may evaluate conditions as indicated by the input data and outputs the lower and upper SoC thresholds that have historically led to minimal degradation in similar situations. As such, the machine learning model may function as an EV battery longevity optimizer by leveraging historical patterns of degradation to recommend lower and upper SoC thresholds that lead to the least stress on the EV battery over extended use.

In step 709, the assessment platform 101 generates a vehicle navigation function based on the lower SoC threshold and the upper SoC threshold. In one embodiment, the vehicle navigation function involves using the lower and upper SoC thresholds generated by the machine learning model to incorporate one or more charging sessions into the trip to be taken by the EV of interest to ensure that the SoC of the EV of interest is greater than the lower SoC threshold during the trip and lesser than the upper SoC threshold during the trip. In one embodiment, the one or more charging sessions is strategically planned for the trip to enable the EV of interest to travel at a maximum distance during the trip without compromising the lower SoC threshold and upper SoC threshold. In one embodiment, the vehicle navigation function involves generating vehicle maneuver instructions for traversing the trip. In one embodiment, the vehicle navigation function may be autonomous vehicle maneuver instructions/control commands.

In step 711, the assessment platform 101 outputs the vehicle navigation function to the EV of interest, a user equipment associated with a user of the EV of interest, or a combination thereof. In one embodiment, the assessment platform 101 outputs the vehicle navigation function by presenting various information on a user interface, such as a user interface of an infotainment system of a vehicle, user equipment, such as the UE 113, or a combination thereof. For example such information may include: (i) a route to a destination; (ii) graphical representations of a real-time perspective view of a region including the EV of interest; (iii) a heading and position of the EV of interest; (iv) objects within the region (e.g., roads, road objects, buildings, points-of-interest, other vehicles, etc.); (v) a maneuver instruction for a current road portion on which the EV of interest is currently traversing; (vi) one or more subsequent maneuver instructions for one or more subsequent road portions of the route; (vii) a lower SoC threshold for the route; (viii) an upper SoC threshold for an upcoming charging session; (ix) estimated time of arrival (ETA); (x) a speed limit for the road portion; (xi) an amount of distance of travel for the road portion; (xii) a current SoC of the EV of interest; (xiii) names of the road portion and one or more subsequent road portions of the route; (xiv) an amount of energy required to traverse from the current location of the EV of interest to the destination; (xv) other relevant information pertaining to navigation of the route; or (xvi) a combination thereof. In one embodiment, the of interest may be an autonomous vehicle, and the assessment platform 101 may output autonomous vehicle maneuver instructions/control commands as the vehicle navigation function to the EV.

Returning to FIG. 1, as shown and discussed above, the system 100 includes the assessment platform 101 for determining lower and upper SoC thresholds, according to an embodiment of the invention. In one embodiment, the assessment platform 101 has connectivity or access to one or more databases for storing the training data 103 and the output data 111 determined according to the various embodiments described herein, and as well as a database 117 for retrieving mapping data and/or related attributes for outputting the output data 111.

In the illustrated embodiment, the UE 113 has connectivity to the assessment platform 101 via the communication network 125. The UE 113 may be any type of mobile terminal or fixed terminal such as a mobile handset, station, unit, device, multimedia computer, multimedia tablet, Internet node, communicator, cellular telephone, desktop computer, laptop computer, notebook computer, netbook computer, tablet computer, personal communication system (PCS) device, personal digital assistants (PDAs), audio/video player, digital camera/camcorder, positioning device, fitness device, television receiver, radio broadcast receiver, electronic book device, game device, devices associated with or integrated with a vehicle (e.g., as part of an infotainment system), or any combination thereof, including the accessories and peripherals of these devices. In one embodiment, the UE 113 can be an in-vehicle navigation system, a personal navigation device (PND), a portable navigation device, a cellular telephone, a mobile phone, a personal digital assistant (PDA), a watch, a camera, a computer, and/or other device that can perform navigation-related functions, such as digital routing and map display. In one embodiment, the UE 113 may support any type of interface to the user (such as “wearable” devices, etc.).

In the illustrated embodiment, an application 115 may be executable by the UE 113 to provide one or more applications related to the output data 111. In one embodiment, the application 1153 may provide the vehicle navigation function by outputting information included in the output data 111 on a user interface of the UE 113. In one embodiment, the application 115 may another application that is executable by the UE 113, such as a mapping application, a location-based service application, a navigation application, a content provisioning service, a camera/imaging application, a media player application, a social networking application, a calendar application, or any combination thereof. In one embodiment, the application 115 may act as clients for the assessment platform 101 and perform one or more functions associated with the functions of the assessment platform 101 by interacting with the assessment platform 101 over the communication network 125.

In the illustrated embodiment, the detection entities 107 may be vehicles, drones, user equipment, and/or road-side sensors. In the illustrated embodiment, the detection entities 117 include sensors 109a-109n (collectively referred as sensors 109). The sensors 109 may be electronic imaging devices of both analog and digital types, which include digital cameras, camera modules, camera phones, thermal imaging devices, radar, sonar, lidar, etc. The detection entities 107 may further include a network detection sensor for detecting wireless signals or receivers for different short-range communications (e.g., Bluetooth, Wi-Fi, Li-Fi, near field communication (NFC), etc.), temporal information sensors, an audio recorder for gathering audio data, velocity sensors, light sensors, oriental sensors augmented with height sensor and acceleration sensor, tilt sensors to detect the degree of incline or decline of each of the detection entities 107 along a path of travel, etc. In one embodiment, the sensors 109 may include one or more sensors disposed around the perimeter of each detection entities 107, and said one or more sensors may detect the relative distance of the detection entity 107 from road objects, lanes, or roadways, the presence of other vehicles, pedestrians, traffic lights, road features (e.g., curves) and any other objects, or a combination thereof. In one embodiment, the sensors 109 may also detect orientations of objects. In one embodiment, the detection entities 107 may include GPS receivers to obtain geographic coordinates from satellites for determining current locations associated with the detection entities 107. The detection entities 107 may determine such locations by using a triangulation system such as A-GPS, Cell of Origin, or other location extrapolation technologies. The detection entities 107 may further include receivers/transmitters for maintaining communication with the assessment platform 101 and/or other components within the system 100.

In one embodiment, the assessment platform 101 has connectivity over a communication network 125 to the services platform 119 that provides one or more services 121. By way of example, the services 121 may be third-party services that rely on location-based services created or developed based on the output data 111 generated according to the various embodiments described herein. By way of example, the services 121 include, but are not limited to, autonomous/semi-autonomous vehicle operation, mapping services, navigation services, travel planning services, notification services, social networking services, content (e.g., audio, video, images, etc.) provisioning services, application services, storage services, contextual information determination services, location-based services, information-based services (e.g., weather, news, etc.), etc. In one embodiment, the services 121 uses the output of the assessment platform 101.

In one embodiment, the assessment platform 101 may be a platform with multiple interconnected components. The assessment platform 101 may include multiple servers, intelligent networking devices, computing devices, components, and corresponding software for determining lower and upper SoC thresholds and planning charging sessions based on the thresholds. In addition, it is noted that the assessment platform 101 may be a separate entity of the system 100, a part of the one or more services 121, a part of the services platform 119, or included within the UE 113.

In one embodiment, content providers 123 may provide content or data (e.g., training data 115, etc.) to the assessment platform 101, the services platform 119, the services 121 and/or the UE 113. The content provided may also include any type of content, lane level road topology data, sensor data, map content, textual content, audio content, video content, image content, etc. used for map matching. In one embodiment, the content providers 123 may also store content associated with the assessment platform 101, the database 117, the services platform 119, the services 121, and/or the UE 113. In another embodiment, the content providers 123 may manage access to a central repository of data, and offer a consistent, standard interface to data, such as a repository of the database 117.

In one embodiment, the communication network 125 of system 100 includes one or more networks such as a data network, a wireless network, a telephony network, or any combination thereof. It is contemplated that the data network may be any local area network (LAN), metropolitan area network (MAN), wide area network (WAN), a public data network (e.g., the Internet), short range wireless network, or any other suitable packet-switched network, such as a commercially owned, proprietary packet-switched network, e.g., a proprietary cable or fiber-optic network, and the like, or any combination thereof. In addition, the wireless network may be, for example, a cellular network and may employ various technologies including enhanced data rates for global evolution (EDGE), general packet radio service (GPRS), global system for mobile communications (GSM), Internet protocol multimedia subsystem (IMS), universal mobile telecommunications system (UMTS), etc., as well as any other suitable wireless medium, e.g., worldwide interoperability for microwave access (WiMAX), 5G New Radio Networks, Long Term Evolution (LTE) networks, code division multiple access (CDMA), wideband code division multiple access (WCDMA), wireless fidelity (Wi-Fi), wireless LAN (WLAN), Bluetooth®, Internet Protocol (IP) data casting, satellite, mobile ad-hoc network (MANET), and the like, or any combination thereof.

In one embodiment, the assessment platform 101, UE 113, services platform 119, services 121, and/or content providers 123 optionally communicate with each other and other components of the system 100 using well known, new or still developing protocols. In this context, a protocol includes a set of rules defining how the network nodes within the communication network 123 interact with each other based on information sent over the communication links. The protocols are effective at different layers of operation within each node, from generating and receiving physical signals of various types, to selecting a link for transferring those signals, to the format of information indicated by those signals, to identifying which software application executing on a computer system sends or receives the information. The conceptually different layers of protocols for exchanging information over a network are described in the Open Systems Interconnection (OSI) Reference Model.

Communications between the network nodes are typically effected by exchanging discrete packets of data. Each packet typically comprises (1) header information associated with a particular protocol, and (2) payload information that follows the header information and contains information that may be processed independently of that particular protocol. In some protocols, the packet includes (3) trailer information following the payload and indicating the end of the payload information. The header includes information such as the source of the packet, its destination, the length of the payload, and other properties used by the protocol. Often, the data in the payload for the particular protocol includes a header and payload for a different protocol associated with a different, higher layer of the OSI Reference Model. The header for a particular protocol typically indicates a type for the next protocol contained in its payload. The higher layer protocol is said to be encapsulated in the lower layer protocol. The headers included in a packet traversing multiple heterogeneous networks, such as the Internet, typically include a physical (layer 1) header, a datalink (layer 2) header, an internetwork (layer 3) header and a transport (layer 4) header, and various application (layer 5, layer 6 and layer 7) headers as defined by the OSI Reference Model.

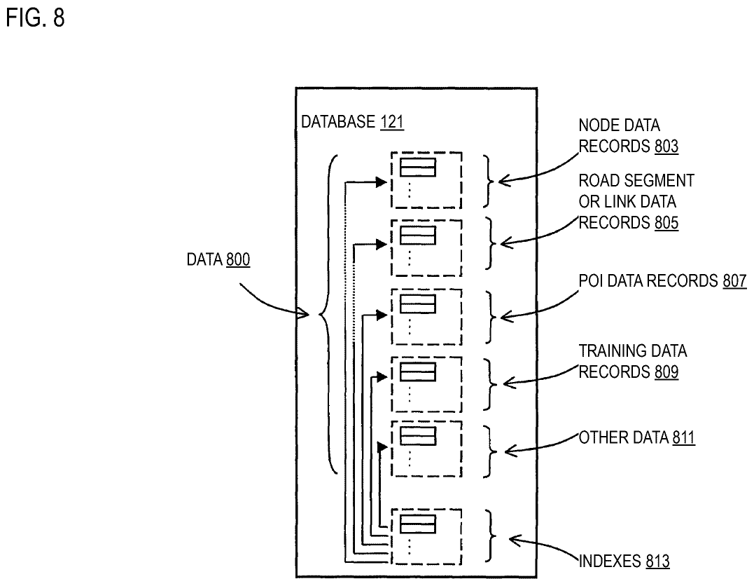

FIG. 8 is a diagram of the database 117, according to an embodiment. In one embodiment, the database 117 includes data 800 used for (or configured to be compiled to be used for) mapping and/or navigation-related services. In one embodiment, the database 117 includes geographic features (e.g., two-dimensional or three-dimensional features) represented using polygons (e.g., two-dimensional features) or polygon extrusions (e.g., three-dimensional features). For example, the edges of the polygons correspond to the boundaries or edges of the respective geographic feature. In the case of a building, a two-dimensional polygon can be used to represent a footprint of the building, and a three-dimensional polygon extrusion can be used to represent the three-dimensional surfaces of the building. It is contemplated that although various embodiments are discussed with respect to two-dimensional polygons, it is contemplated that the embodiments are also applicable to three-dimensional polygon extrusions. Accordingly, the terms polygons and polygon extrusions as used herein can be used interchangeably.

In one embodiment, the following terminology applies to the representation of geographic features in the database 117.
“Node”—A point that terminates a link.
“Line segment”—A straight line connecting two points.
“Link” (or “edge”)—A contiguous, non-branching string of one or more line segments terminating in a node at each end.
“Shape point”—A point along a link between two nodes (e.g., used to alter a shape of the link without defining new nodes).
“Oriented link”—A link that has a starting node (referred to as the “reference node”) and an ending node (referred to as the “non reference node”).
“Simple polygon”—An interior area of an outer boundary formed by a string of oriented links that begins and ends in one node. In one embodiment, a simple polygon does not cross itself.
“Polygon”—An area bounded by an outer boundary and none or at least one interior boundary (e.g., a hole or island). In one embodiment, a polygon is constructed from one outer simple polygon and none or at least one inner simple polygon. A polygon is simple if it just consists of one simple polygon, or complex if it has at least one inner simple polygon.

In one embodiment, the database 117 follows certain conventions. For example, links do not cross themselves and do not cross each other except at a node. Also, there are no duplicated shape points, nodes, or links. Two links that connect each other have a common node. In the database 117, overlapping geographic features are represented by overlapping polygons. When polygons overlap, the boundary of one polygon crosses the boundary of the other polygon. In the database 117, the location at which the boundary of one polygon intersects the boundary of another polygon is represented by a node. In one embodiment, a node may be used to represent other locations along the boundary of a polygon than a location at which the boundary of the polygon intersects the boundary of another polygon. In one embodiment, a shape point is not used to represent a point at which the boundary of a polygon intersects the boundary of another polygon.

As shown, the database 117 includes node data records 803, road segment or link data records 805, POI data records 807, training data records 809, other data 811, and indexes 813, for example. More, fewer, or different data records can be provided. In one embodiment, additional data records (not shown) can include cartographic (“carto”) data records, routing data, and maneuver data. In one embodiment, the indexes 813 may improve the speed of data retrieval operations in the database 117. In one embodiment, the indexes 813 may be used to quickly locate data without having to search every row in the database 117 every time it is accessed. For example, in one embodiment, the indexes 813 can be a spatial index of the polygon points associated with stored feature polygons.

In exemplary embodiments, the road segment or link data records 805 are links or segments representing roads, streets, or paths, as can be used in the calculated route or recorded route information for determination of one or more personalized routes. The node data records 803 are end points (such as intersections) corresponding to the respective links or segments of the road segment or link data records 805. The road segment or link data records 805 and the node data records 803 represent a road network, such as used by vehicles, cars, and/or other entities. Alternatively, the database 117 can contain path segment and node data records or other data that represent pedestrian paths or areas in addition to or instead of the vehicle road record data, for example.

The road/link segments and nodes can be associated with attributes, such as geographic coordinates, street names, address ranges, speed limits, turn restrictions at intersections, and other navigation related attributes, as well as POIs, such as gasoline stations, hotels, restaurants, museums, stadiums, offices, automobile dealerships, auto repair shops, buildings, stores, parks, etc. The database 117 can include data about the POIs and their respective locations in the POI data records 807. The database 117 can also include data about places, such as cities, towns, or other communities, and other geographic features, such as bodies of water, mountain ranges, etc. Such place or feature data can be part of the POI data records 807 or can be associated with POIs or POI data records 807 (such as a data point used for displaying or representing a position of a city).

In one embodiment, the database 117 can also include training data records 809 for storing training data 103, and/or any related data generated or used according to the various embodiments described herein. In one embodiment, the training data records 809 can be associated with one or more of the node records 803, road segment records 805, and/or POI data records 807 to associate the training data 103 with specific geographic locations. In this way, the training data 103 can also be associated with the characteristics or metadata of the corresponding records 803, 805, and/or 807.

In one embodiment, the data 800 can also include other data 811 such as data used for evaluating the machine learning model 301. For example, testing dataset that assesses the machine learning model's performance may be stored as other data 811. Additionally, data for tuning and optimizing the machine learning model 301 may be stored as other data 811. For example, data for adjusting the machine learning model's hyperparameters may be stored as other data 811. Other 811 may also include ground truth data that may be used to compare against the output data 111 and fine tune the machine learning model 301 based on the comparison. Other data 811 data may also include information pertaining to vehicles, features related to trips taken by the vehicles, or a combination thereof.

In one embodiment, the database 117 can be maintained by the content providers 123 in association with the services platform 119 (e.g., a map developer). The map developer can collect geographic data to generate and enhance the database 117. There can be different ways used by the map developer to collect data. These ways can include obtaining data from other sources, such as municipalities or respective geographic authorities. In addition, the map developer can employ field personnel to travel by vehicle (e.g., vehicle) along roads throughout the geographic region to observe features and/or record information about them, for example. Also, remote sensing, such as aerial or satellite photography, can be used.

The database 117 can be a master geographic database stored in a format that facilitates updating, maintenance, and development. For example, the master geographic database or data in the master geographic database can be in an Oracle spatial format or other spatial format, such as for development or production purposes. Map layers may be utilized. The Oracle spatial format or development/production database can be compiled into a delivery format, such as a geographic data files (GDF) format. The data in the production and/or delivery formats can be compiled or further compiled to form geographic database products or databases, which can be used in end user navigation devices or systems.

For example, geographic data is compiled (such as into a platform specification format (PSF) format) to organize and/or configure the data for performing navigation-related functions and/or services, such as route calculation, route guidance, map display, speed calculation, distance and travel time functions, and other functions, by a navigation device. The navigation-related functions can correspond to vehicle navigation, pedestrian navigation, or other types of navigation. The compilation to produce the end user databases can be performed by a party or entity separate from the map developer. For example, a customer of the map developer, such as a navigation device developer or other end user device developer, can perform compilation on a received geographic database in a delivery format to produce one or more compiled navigation databases.

The processes described herein for determining upper and lower SoC thresholds may be advantageously implemented via software, hardware (e.g., general processor, Digital Signal Processing (DSP) chip, an Application Specific Integrated Circuit (ASIC), Field Programmable Gate Arrays (FPGAs), etc.), firmware or a combination thereof. Such exemplary hardware for performing the described functions is detailed below.

Additionally, as used herein, the term ‘circuitry’ may refer to (a) hardware-only circuit implementations (for example, implementations in analog circuitry and/or digital circuitry); (b) combinations of circuits and computer program product(s) comprising software and/or firmware instructions stored on one or more computer readable memories that work together to cause an apparatus to perform one or more functions described herein; and (c) circuits, such as, for example, a microprocessor(s) or a portion of a microprocessor(s), that require software or firmware for operation even if the software or firmware is not physically present. This definition of ‘circuitry’ applies to all uses of this term herein, including in any claims. As a further example, as used herein, the term ‘circuitry’ also includes an implementation comprising one or more processors and/or portion(s) thereof and accompanying software and/or firmware. As another example, the term ‘circuitry’ as used herein also includes, for example, a baseband integrated circuit or applications processor integrated circuit for a mobile phone or a similar integrated circuit in a server, a cellular device, other network device, and/or other computing device.

The system, apparatus, and methods described herein provide various approaches for determining lower and upper SoC thresholds for optimizing EV battery life and planning charging sessions into trips to be taken by EVs to ensure that the thresholds are not compromised during the trips, thereby minimizing EV battery degradation during usage. Specifically, the lower and upper SoC thresholds are determined via use of a machine learning model that is trained with training data including input-output pairs, where the output of each pair includes features such as the lowest SoC level of an EV battery during a trip and the highest SoC level of the EV battery during the trip, and the input of each pair includes features such as vehicle power supply information, vehicle specification, driving behavior, road attributes, environmental attributes, attributes regarding EV charging sessions, trip-related attributes, etc. Since the trained machine learning model predicts the optimal lower and upper SoC thresholds for improving battery longevity by evaluating conditions as indicated by input data and outputs lower and upper SoC thresholds that have historically led to minimal degradation in similar situations, the lower and upper SoC thresholds and the charging session plans provided via the approaches described herein are advantageous over lower and upper SoC thresholds recommended through conventional research and industry practices.

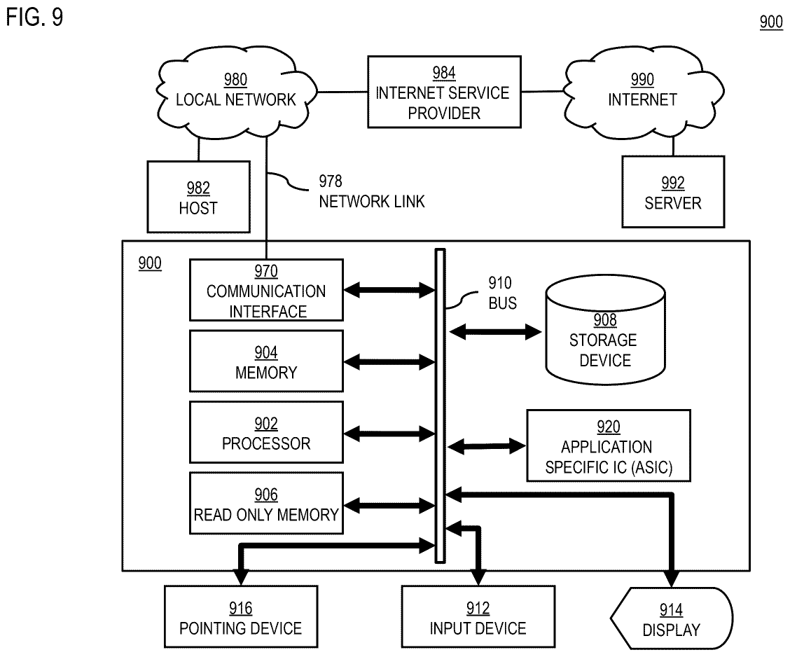

FIG. 9 illustrates a computer system 900 upon which an embodiment of the invention may be implemented. Computer system 900 is programmed (e.g., via computer program code or instructions) to determine upper and lower SoC thresholds as described herein and includes a communication mechanism such as a bus 910 for passing information between other internal and external components of the computer system 900. Information (also called data) is represented as a physical expression of a measurable phenomenon, typically electric voltages, but including, in other embodiments, such phenomena as magnetic, electromagnetic, pressure, chemical, biological, molecular, atomic, sub-atomic and quantum interactions. For example, north and south magnetic fields, or a zero and non-zero electric voltage, represent two states (0, 1) of a binary digit (bit). Other phenomena can represent digits of a higher base. A superposition of multiple simultaneous quantum states before measurement represents a quantum bit (qubit). A sequence of one or more digits constitutes digital data that is used to represent a number or code for a character. In some embodiments, information called analog data is represented by a near continuum of measurable values within a particular range.

A bus 910 includes one or more parallel conductors of information so that information is transferred quickly among devices coupled to the bus 910. One or more processors 902 for processing information are coupled with the bus 910.

A processor 902 performs a set of operations on information as specified by computer program code related to determining upper and lower SoC thresholds. The computer program code is a set of instructions or statements providing instructions for the operation of the processor and/or the computer system to perform specified functions. The code, for example, may be written in a computer programming language that is compiled into a native instruction set of the processor. The code may also be written directly using the native instruction set (e.g., machine language). The set of operations include bringing information in from the bus 910 and placing information on the bus 910. The set of operations also typically include comparing two or more units of information, shifting positions of units of information, and combining two or more units of information, such as by addition or multiplication or logical operations like OR, exclusive OR (XOR), and AND. Each operation of the set of operations that can be performed by the processor is represented to the processor by information called instructions, such as an operation code of one or more digits. A sequence of operations to be executed by the processor 902, such as a sequence of operation codes, constitute processor instructions, also called computer system instructions or, simply, computer instructions. Processors may be implemented as mechanical, electrical, magnetic, optical, chemical or quantum components, among others, alone or in combination.

Computer system 900 also includes a memory 904 coupled to bus 910. The memory 904, such as a random access memory (RAM) or other dynamic storage device, stores information including processor instructions for determining upper and lower SoC thresholds. Dynamic memory allows information stored therein to be changed by the computer system 900. RAM allows a unit of information stored at a location called a memory address to be stored and retrieved independently of information at neighboring addresses. The memory 904 is also used by the processor 902 to store temporary values during execution of processor instructions. The computer system 900 also includes a read only memory (ROM) 906 or other static storage device coupled to the bus 910 for storing static information, including instructions, that is not changed by the computer system 900. Some memory is composed of volatile storage that loses the information stored thereon when power is lost. Also coupled to bus 910 is a non-volatile (persistent) storage device 908, such as a magnetic disk, optical disk or flash card, for storing information, including instructions, that persists even when the computer system 900 is turned off or otherwise loses power.

Information, including instructions for determining upper and lower SoC thresholds, is provided to the bus 910 for use by the processor from an external input device 912, such as a keyboard containing alphanumeric keys operated by a human user, or a sensor. A sensor detects conditions in its vicinity and transforms those detections into physical expression compatible with the measurable phenomenon used to represent information in computer system 900. Other external devices coupled to bus 910, used primarily for interacting with humans, include a display device 914, such as a cathode ray tube (CRT) or a liquid crystal display (LCD), or plasma screen or printer for presenting text or images, and a pointing device 916, such as a mouse or a trackball or cursor direction keys, or motion sensor, for controlling a position of a small cursor image presented on the display 914 and issuing commands associated with graphical elements presented on the display 914. In some embodiments, for example, in embodiments in which the computer system 900 performs all functions automatically without human input, one or more of external input device 912, display device 914 and pointing device 916 is omitted.

In the illustrated embodiment, special purpose hardware, such as an application specific integrated circuit (ASIC) 920, is coupled to bus 910. The special purpose hardware is configured to perform operations not performed by processor 902 quickly enough for special purposes. Examples of application specific ICs include graphics accelerator cards for generating images for display 914, cryptographic boards for encrypting and decrypting messages sent over a network, speech recognition, and interfaces to special external devices, such as robotic arms and medical scanning equipment that repeatedly perform some complex sequence of operations that are more efficiently implemented in hardware.

Computer system 900 also includes one or more instances of a communications interface 970 coupled to bus 910. Communication interface 970 provides a one-way or two-way communication coupling to a variety of external devices that operate with their own processors, such as printers, scanners and external disks. In general, the coupling is with a network link 978 that is connected to a local network 980 to which a variety of external devices with their own processors are connected. For example, communication interface 970 may be a parallel port or a serial port or a universal serial bus (USB) port on a personal computer. In some embodiments, communications interface 970 is an integrated services digital network (ISDN) card or a digital subscriber line (DSL) card or a telephone modem that provides an information communication connection to a corresponding type of telephone line. In some embodiments, a communication interface 970 is a cable modem that converts signals on bus 910 into signals for a communication connection over a coaxial cable or into optical signals for a communication connection over a fiber optic cable. As another example, communications interface 970 may be a local area network (LAN) card to provide a data communication connection to a compatible LAN, such as Ethernet. Wireless links may also be implemented. For wireless links, the communications interface 970 sends or receives or both sends and receives electrical, acoustic or electromagnetic signals, including infrared and optical signals, that carry information streams, such as digital data. For example, in wireless handheld devices, such as mobile telephones like cell phones, the communications interface 970 includes a radio band electromagnetic transmitter and receiver called a radio transceiver. In certain embodiments, the communications interface 970 enables connection to the communication network 125 for determining upper and lower SoC thresholds.

The term computer-readable medium is used herein to refer to any medium that participates in providing information to processor 902, including instructions for execution. Such a medium may take many forms, including, but not limited to, non-volatile media, volatile media and transmission media. Non-volatile media include, for example, optical or magnetic disks, such as storage device 908. Volatile media include, for example, dynamic memory 904. Transmission media include, for example, coaxial cables, copper wire, fiber optic cables, and carrier waves that travel through space without wires or cables, such as acoustic waves and electromagnetic waves, including radio, optical and infrared waves. Signals include man-made transient variations in amplitude, frequency, phase, polarization or other physical properties transmitted through the transmission media. Common forms of computer-readable media include, for example, a floppy disk, a flexible disk, hard disk, magnetic tape, any other magnetic medium, a CD-ROM, CDRW, DVD, any other optical medium, punch cards, paper tape, optical mark sheets, any other physical medium with patterns of holes or other optically recognizable indicia, a RAM, a PROM, an EPROM, a FLASH-EPROM, any other memory chip or cartridge, a carrier wave, or any other medium from which a computer can read.

Network link 978 typically provides information communication using transmission media through one or more networks to other devices that use or process the information. For example, network link 978 may provide a connection through local network 980 to a host computer 982 or to equipment 984 operated by an Internet Service Provider (ISP). ISP equipment 984 in turn provides data communication services through the public, world-wide packet-switching communication network of networks now commonly referred to as the Internet 990.

A computer called a server host 992 connected to the Internet hosts a process that provides a service in response to information received over the Internet. For example, server host 992 hosts a process that provides information representing video data for presentation at display 914. It is contemplated that the components of system can be deployed in various configurations within other computer systems, e.g., host 982 and server 992.

FIG. 10 illustrates a diagram of a chip set 1000 upon which an embodiment of the invention may be implemented. Chip set 1000 is programmed to determine upper and lower SoC thresholds as described herein and includes, for instance, the processor and memory components described with respect to FIG. 9 incorporated in one or more physical packages (e.g., chips). By way of example, a physical package includes an arrangement of one or more materials, components, and/or wires on a structural assembly (e.g., a baseboard) to provide one or more characteristics such as physical strength, conservation of size, and/or limitation of electrical interaction. It is contemplated that in certain embodiments the chip set can be implemented in a single chip.

In one embodiment, the chip set 1000 includes a communication mechanism such as a bus 1001 for passing information among the components of the chip set 1000. A processor 1003 has connectivity to the bus 1001 to execute instructions and process information stored in, for example, a memory 1005. The processor 1003 may include one or more processing cores with each core configured to perform independently. A multi-core processor enables multiprocessing within a single physical package. Examples of a multi-core processor include two, four, eight, or greater numbers of processing cores. Alternatively or in addition, the processor 1003 may include one or more microprocessors configured in tandem via the bus 1001 to enable independent execution of instructions, pipelining, and multithreading. The processor 1003 may also be accompanied with one or more specialized components to perform certain processing functions and tasks such as one or more digital signal processors (DSP) 1007, or one or more application-specific integrated circuits (ASIC) 1009. A DSP 1007 typically is configured to process real-world signals (e.g., sound) in real time independently of the processor 1003. Similarly, an ASIC 1009 can be configured to perform specialized functions not easily performed by a general purposed processor. Other specialized components to aid in performing the inventive functions described herein include one or more field programmable gate arrays (FPGA) (not shown), one or more controllers (not shown), or one or more other special-purpose computer chips.

The processor 1003 and accompanying components have connectivity to the memory 1005 via the bus 1001. The memory 1005 includes both dynamic memory (e.g., RAM, magnetic disk, writable optical disk, etc.) and static memory (e.g., ROM, CD-ROM, etc.) for storing executable instructions that when executed perform the inventive steps described herein to determine upper and lower SoC thresholds. The memory 1005 also stores the data associated with or generated by the execution of the inventive steps.

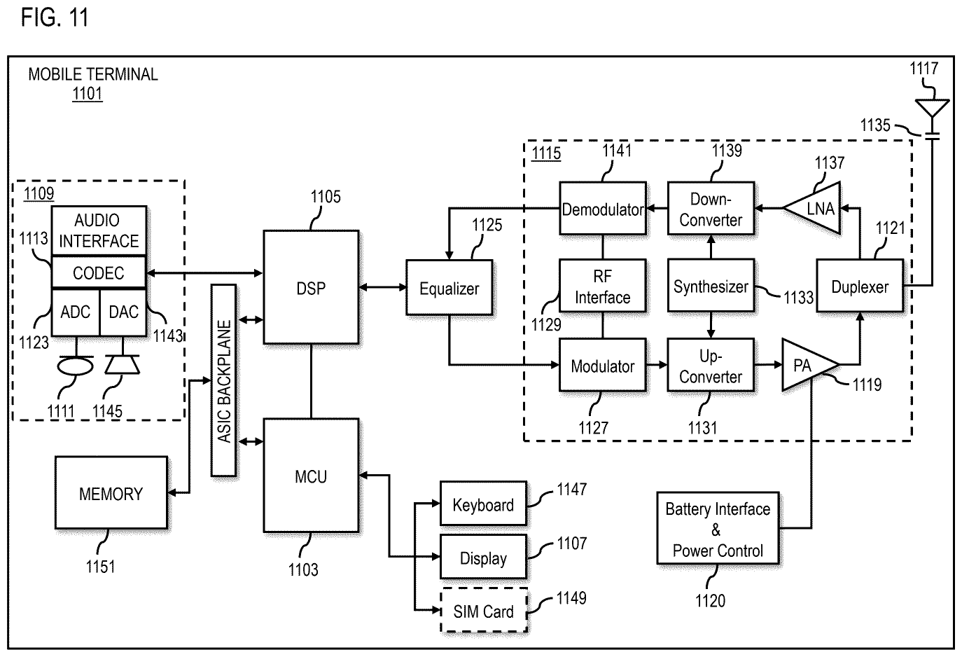

FIG. 11 illustrates a diagram of exemplary components of a mobile terminal capable of operating in the system of FIG. 1, according to one embodiment. In the illustrated embodiment, a mobile terminal 1100 is provided. Generally, a radio receiver is often defined in terms of front-end and back-end characteristics. The front end of the receiver encompasses all of the Radio Frequency (RF) circuitry whereas the back end encompasses all of the base-band processing circuitry. Pertinent internal components of the telephone include a Main Control Unit (MCU) 1103, a Digital Signal Processor (DSP) 1105, and a receiver/transmitter unit including a microphone gain control unit and a speaker gain control unit. A main display unit 1107 provides a display to the user in support of various applications and mobile station functions that offer automatic contact matching. An audio function circuitry 1109 includes a microphone 1111 and microphone amplifier that amplifies the speech signal output from the microphone 1111. The amplified speech signal output from the microphone 1111 is fed to a coder/decoder (CODEC) 1113.

A radio section 1115 amplifies power and converts frequency in order to communicate with a base station, which is included in a mobile communication system, via antenna 1117. The power amplifier (PA) 1119 and the transmitter/modulation circuitry are operationally responsive to the MCU 1103, with an output from the PA 1119 coupled to the duplexer 1121 or circulator or antenna switch, as known in the art. The PA 1119 also couples to a battery interface and power control unit 1120.

In use, a user of mobile station 1101 speaks into the microphone 1111 and his or her voice along with any detected background noise is converted into an analog voltage. The analog voltage is then converted into a digital signal through the Analog to Digital Converter (ADC) 1123. The control unit 1103 routes the digital signal into the DSP 1105 for processing therein, such as speech encoding, channel encoding, encrypting, and interleaving. In one embodiment, the processed voice signals are encoded, by units not separately shown, using a cellular transmission protocol such as global evolution (EDGE), general packet radio service (GPRS), global system for mobile communications (GSM), Internet protocol multimedia subsystem (IMS), universal mobile telecommunications system (UMTS), etc., as well as any other suitable wireless medium, e.g., microwave access (WiMAX), Long Term Evolution (LTE) networks, 5G New Radio networks, code division multiple access (CDMA), wireless fidelity (WiFi), satellite, and the like.

The encoded signals are then routed to an equalizer 1125 for compensation of any frequency-dependent impairments that occur during transmission though the air such as phase and amplitude distortion. After equalizing the bit stream, the modulator 1127 combines the signal with a RF signal generated in the RF interface 1129. The modulator 1127 generates a sine wave by way of frequency or phase modulation. In order to prepare the signal for transmission, an up-converter 1131 combines the sine wave output from the modulator 1127 with another sine wave generated by a synthesizer 1133 to achieve the desired frequency of transmission. The signal is then sent through a PA 1119 to increase the signal to an appropriate power level. In practical systems, the PA 1119 acts as a variable gain amplifier whose gain is controlled by the DSP 1105 from information received from a network base station. The signal is then filtered within the duplexer 1121 and optionally sent to an antenna coupler 1135 to match impedances to provide maximum power transfer. Finally, the signal is transmitted via antenna 1117 to a local base station. An automatic gain control (AGC) can be supplied to control the gain of the final stages of the receiver. The signals may be forwarded from there to a remote telephone which may be another cellular telephone, other mobile phone or a land-line connected to a Public Switched Telephone Network (PSTN), or other telephony networks.

Voice signals transmitted to the mobile station 1101 are received via antenna 1117 and immediately amplified by a low noise amplifier (LNA) 1137. A down-converter 1139 lowers the carrier frequency while the demodulator 1141 strips away the RF leaving only a digital bit stream. The signal then goes through the equalizer 1125 and is processed by the DSP 1105. A Digital to Analog Converter (DAC) 1143 converts the signal and the resulting output is transmitted to the user through the speaker 1145, all under control of a Main Control Unit (MCU) 1103—which can be implemented as a Central Processing Unit (CPU) (not shown).

The MCU 1103 receives various signals including input signals from the keyboard 1147. The keyboard 1147 and/or the MCU 1103 in combination with other user input components (e.g., the microphone 1111) comprise a user interface circuitry for managing user input. The MCU 1103 runs a user interface software to facilitate user control of at least some functions of the mobile station 1101 to determine upper and lower SoC thresholds. The MCU 1103 also delivers a display command and a switch command to the display 1107 and to the speech output switching controller, respectively. Further, the MCU 1103 exchanges information with the DSP 1105 and can access an optionally incorporated SIM card 1149 and a memory 1151. In addition, the MCU 1103 executes various control functions required of the station. The DSP 1105 may, depending upon the implementation, perform any of a variety of conventional digital processing functions on the voice signals. Additionally, DSP 1105 determines the background noise level of the local environment from the signals detected by microphone 1111 and sets the gain of microphone 1111 to a level selected to compensate for the natural tendency of the user of the mobile station 1101.

The CODEC 1113 includes the ADC 1123 and DAC 1143. The memory 1151 stores various data including call incoming tone data and is capable of storing other data including music data received via, e.g., the global Internet. The software module could reside in RAM memory, flash memory, registers, or any other form of writable computer-readable storage medium known in the art including non-transitory computer-readable storage medium. For example, the memory device 1151 may be, but not limited to, a single memory, CD, DVD, ROM, RAM, EEPROM, optical storage, or any other non-volatile or non-transitory storage medium capable of storing digital data.

An optionally incorporated SIM card 1149 carries, for instance, important information, such as the cellular phone number, the carrier supplying service, subscription details, and security information. The SIM card 1149 serves primarily to identify the mobile station 1101 on a radio network. The card 1149 also contains a memory for storing a personal telephone number registry, text messages, and user specific mobile station settings.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. An apparatus comprising at least one processor and at least one non-transitory memory including computer program code instructions, the computer program code instructions configured to, when executed, cause the apparatus to:
receive training data indicating features of vehicles and trips taken by the vehicles;
train a machine learning model to generate a lower state of charge (SoC) threshold and an upper SoC threshold for a vehicle based on the training data;
receive input data associated with the vehicle, the input data corresponding to the training data;
cause the machine learning model to output the lower SoC threshold and the upper SoC threshold based on the input data;
generate a vehicle navigation function based on the lower SoC threshold and the upper SoC threshold; and
output the vehicle navigation function to the vehicle, a user equipment associated with a user of the vehicle, or a combination thereof.

2. The apparatus of claim 1, wherein the lower SoC threshold and the upper SoC threshold define a recommended range for maintaining a SoC of the vehicle during a trip to be taken by the vehicle.

3. The apparatus of claim 1, wherein the features indicate charging sessions of the vehicles, and wherein the attributes indicate, for each one of the one or more vehicle charging sessions: (i) a first SoC at which said one of the one or more vehicle charging sessions initiated; and (ii) a second SoC at which said one of the one or more vehicle sessions terminated.

4. The apparatus of claim 3, wherein the features indicate: (i) one or more types of charging provided by charging points to the vehicles during the charging sessions; (ii) a duration of each of the one or more vehicle charging sessions; or (iii) a combination thereof.

5. The apparatus of claim 1, wherein the features indicate, for each one of the vehicles: (i) a state of health (SoH) of a battery of said one of the vehicles; (ii) an energy ratio; or (iii) a combination thereof.

6. The apparatus of claim 1, wherein the features indicate attributes of the vehicles, and wherein the attributes indicate: (i) vehicle power supply information; (ii) vehicle specification; or (iii) a combination thereof.

7. The apparatus of claim 1, wherein the features indicate: (i) one or more road attributes of the trips; (ii) driving behaviors associated with the vehicles; (iii) one or more weather conditions associated with the trips; or (iv) a combination thereof.

8. The apparatus of claim 7, wherein the one or more road attributes indicate, for one or more road segments of the trips: (i) a road quality; (ii) a functional class; (iii) a speed limit; (iv) elevation information; (v) a coefficient of friction; (vi) an effective gradient; or (vii) a combination thereof.

9. The apparatus of claim 1, wherein, to generate the vehicle navigation function, the computer program code instructions are configured to, when executed, cause the apparatus to:
generate a trip for the vehicle that incorporates one or more charging sessions at one or more charging points during one or more periods of the trip such that a SoC of the vehicle is greater than the lower SoC threshold and lesser than the upper SoC threshold during the trip; and
generate vehicle maneuver instructions for traversing the trip as the vehicle navigation function.

10. A non-transitory computer-readable storage medium having computer program code instructions stored therein, the computer program code instructions, when executed by at least one processor, cause the at least one processor to:
receive training data indicating features of vehicles and trips taken by the vehicles;
train a machine learning model to generate a lower state of charge (SoC) threshold and an upper SoC threshold for a vehicle based on the training data;
receive input data associated with the vehicle, the input data corresponding to the training data;
cause the machine learning model to output the lower SoC threshold and the upper SoC threshold based on the input data;
generate a vehicle navigation function based on the lower SoC threshold and the upper SoC threshold; and
output the vehicle navigation function to the vehicle, a user equipment associated with a user of the vehicle, or a combination thereof.

11. The non-transitory computer-readable storage medium of claim 10, wherein the lower SoC threshold and the upper SoC threshold define a recommended range for maintaining a SoC of the vehicle during a trip to be taken by the vehicle.

12. The non-transitory computer-readable storage medium of claim 10, wherein the features indicate charging sessions of the vehicles, and wherein the attributes indicate, for each one of the one or more vehicle charging sessions: (i) a first SoC at which said one of the one or more vehicle charging sessions initiated; and (ii) a second SoC at which said one of the one or more vehicle sessions terminated.

13. The non-transitory computer-readable storage medium of claim 12, wherein the features indicate: (i) one or more types of charging provided by charging points to the vehicles during the charging sessions; (ii) a duration of each of the one or more vehicle charging sessions; or (iii) a combination thereof.

14. The non-transitory computer-readable storage medium of claim 10, wherein the features indicate, for each one of the vehicles: (i) a state of health (SoH) of a battery of said one of the vehicles; (ii) an energy ratio; or (iii) a combination thereof.

15. The non-transitory computer-readable storage medium of claim 10, wherein the features indicate attributes of the vehicles, and wherein the attributes indicate: (i) vehicle power supply information; (ii) vehicle specification; or (iii) a combination thereof.

16. A method comprising:
receiving training data indicating features of vehicles and trips taken by the vehicles;
training a machine learning model to generate a lower state of charge (SoC) threshold and an upper SoC threshold for a vehicle based on the training data;
receiving input data associated with the vehicle, the input data corresponding to the training data;
causing the machine learning model to output the lower SoC threshold and the upper SoC threshold based on the input data;
generating a vehicle navigation function based on the lower SoC threshold and the upper SoC threshold; and
outputting the vehicle navigation function to the vehicle, a user equipment associated with a user of the vehicle, or a combination thereof.

17. The method of claim 16, wherein the lower SoC threshold and the upper SoC threshold define a recommended range for maintaining a SoC of the vehicle during a trip to be taken by the vehicle.

18. The method of claim 16, wherein the features indicate charging sessions of the vehicles, and wherein the attributes indicate, for each one of the one or more vehicle charging sessions: (i) a first SoC at which said one of the one or more vehicle charging sessions initiated; and (ii) a second SoC at which said one of the one or more vehicle sessions terminated.

19. The apparatus of claim 18, wherein the features indicate: (i) one or more types of charging provided by charging points to the vehicles during the charging sessions; (ii) a duration of each of the one or more vehicle charging sessions; or (iii) a combination thereof.

20. The method of claim 16, wherein the features indicate, for each one of the vehicles: (i) a state of health (SoH) of a battery of said one of the vehicles; (ii) an energy ratio; or (iii) a combination.
